(19) United States
(12) Patent Application Publication
(10) Pub. No.: US 2026/0344378 A1
(43) Pub. Date: Oct. 29, 2026

(54) METHOD OF FORMING MULTI-GATE TRANSISTORS AND RESULTING STRUCTURES

(71) Applicant: Taiwan Semiconductor Manufacturing Co., Ltd., Hsinchu (TW)

(72) Inventors: Fang Hsuan Hu, Hsinchu (TW); Zhen-Cheng Wu, Taichung City (TW); Yen-Chun Huang, Taipei City (TW); Tze-Liang Lee, Hsinchu (TW)

(21) Appl. No.: 19/731,346

(22) Filed: Jul. 6, 2026

Related U.S. Application Data
(63) Continuation of application No. 18/808,408, filed on Aug. 19, 2024.

(51) Int. Cl. H10P 95/00; H10D 30/01; H10D 62/60; H10D 30/43; H10D 30/67; H10D 62/10; H10D 64/23; H10D 84/83

(52) U.S. Cl. CPC H10P 95/94; H10D 30/014; H10D 62/60; H10D 30/43; H10D 30/6735; H10D 30/6757; H10D 62/121; H10D 64/258; H10D 84/83

(57) ABSTRACT

Forming a semiconductor device includes forming over a surface of a fin a stack of channel regions separated by respective gaps and applying a surface treatment to sidewalls of the channel regions and to the surface of the fin thus causing the sidewalls of the channel regions and the surface of the fin to be less susceptible to deposition of a sacrificial material layer, relative to prior to the surface treatment, and depositing the sacrificial material layer on the channel regions and on the surface of the fin, wherein the surface treatment causes deposition of the sacrificial material to occur to a lesser extent on the sidewalls of the channel regions and the surface of the fin relative to the tops and bottoms of the channel regions, and etching back the sacrificial material layer to form sacrificial material structures within the respective gaps.

### PRIORITY CLAIM AND CROSS-REFERENCE

This application is a continuation of U.S. Patent Application No. 18/808,408, filed on Aug. 19, 2024, which application is hereby incorporated herein by reference.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (nano-FET) in a three-dimensional view, in accordance with some embodiments.

FIGS. 2, 3-4, 5A-5B, 6A-6B, 7A-7C, 8A-8B, 9A-9B, 10A-10B, 11A-11D, 12A-12D, 13A-13D, 14A-14B, 15A-15B, 16A-16B, 17A-17C, 18A-18C, 19A-19C, and FIGS. 20A-20B illustrate varying views of intermediary steps of manufacturing a nano-FET transistor, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In various embodiments, nano-FETs are formed using a process wherein a stack of alternating nano-structures are formed, and further wherein alternate ones of the nano-structures are removed and are replaced with a sacrificial material. As a consequence of forming the sacrificial material, portions of the underlying substrate (fin structure) may become oxidized or may have an extraneous oxide layer formed thereon. This extraneous oxide layer can impact subsequent process steps and can impact performance of the ultimately-formed transistor structure. In some embodiments disclosed herein, a treatment process, such as a nitrogen-containing plasma is performed prior to forming the sacrificial material. The treatment process eliminates or reduces the formation of the extraneous oxide layer.

Embodiments are described below in a particular context, a die comprising nano-FETs. Various embodiments may be applied, however, to dies comprising other types of transistors (e.g., stacking transistors, or the like) in lieu of or in combination with the nano-FETs.

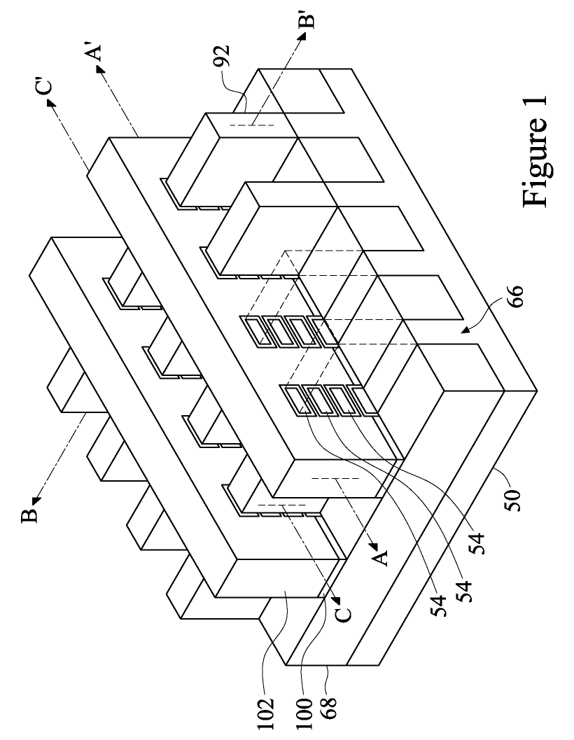

FIG. 1 illustrates an example of nano-FETs (e.g., nanowire FETs, nanosheet FETs (Nano-FETs), or the like) in a three-dimensional view, in accordance with some embodiments. Certain features are simplified and/or omitted in FIG. 1 for ease of illustration. The nano-FETs comprise nanostructures 54 (e.g., nanosheets, nanowire, or the like) over fins 66 on a substrate 50 (e.g., a semiconductor substrate), wherein the nanostructures 54 act as channel regions for the nano-FETs. The nanostructure 54 may include p-type nanostructures, n-type nanostructures, or a combination thereof. STI regions 68 (also referred to as STI structures or STI regions) are disposed between adjacent fins 66, which may protrude above and from between neighboring STI regions 68. Although the STI regions 68 are described/illustrated as being separate from the substrate 50, as used herein, the term “substrate” may refer to the semiconductor substrate alone or a combination of the semiconductor substrate and the isolation regions. Additionally, although a bottom portion of the fins 66 is illustrated as being single, continuous materials with the substrate 50, the bottom portion of the fins 66 and/or the substrate 50 may comprise a single material or a plurality of materials. In this context, the fins 66 refer to the portion extending between the neighboring STI regions 68.

Gate dielectric layers 100 are over top surfaces of the fins 66 and along top surfaces, sidewalls, and bottom surfaces of the nanostructures 54. Gate electrodes 102 are over the gate dielectric layers 100. Epitaxial source/drain regions 92 are disposed on the fins 66 on opposing sides of the gate dielectric layers 100 and the gate electrodes 102. Source/drain region(s) 92 may refer to a source or a drain, individually or collectively dependent upon the context.

FIG. 1 further illustrates reference cross-sections that are used in later figures. Cross-section A-A’ is along a longitudinal axis of a gate electrode 102 and in a direction, for example, perpendicular to the direction of current flow between the epitaxial source/drain regions 92 of a nano-FET. Cross-section B-B’ is perpendicular to cross-section A-A’ and is parallel to a longitudinal axis of a fin 66 of the nano-FET and in a direction of, for example, a current flow between the epitaxial source/drain regions 92 of the nano-FET. Cross-section C-C’ is parallel to cross-section A-A’ and extends through epitaxial source/drain regions of the nano-FETs. Subsequent figures refer to these reference cross-sections for clarity.

Some embodiments discussed herein are discussed in the context of nano-FETs formed using a gate-last process. In other embodiments, a gate-first process may be used. Also, some embodiments contemplate aspects used in planar devices, such as planar FETs or in fin field-effect transistors (FinFETs).

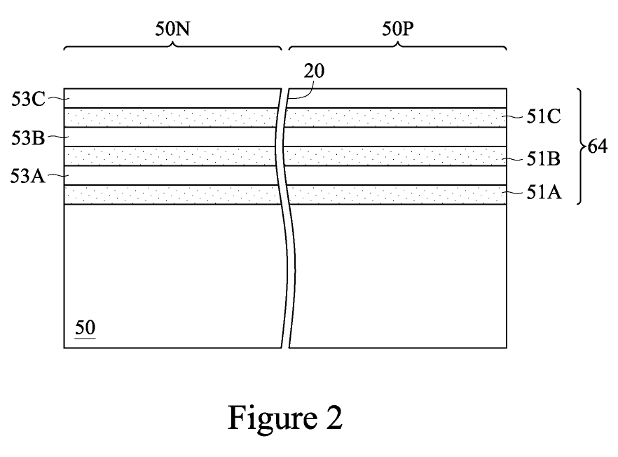

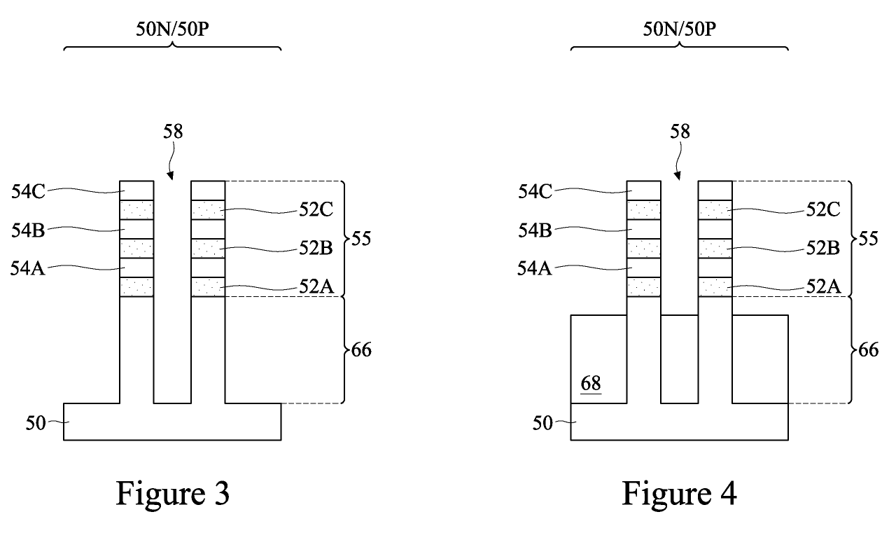

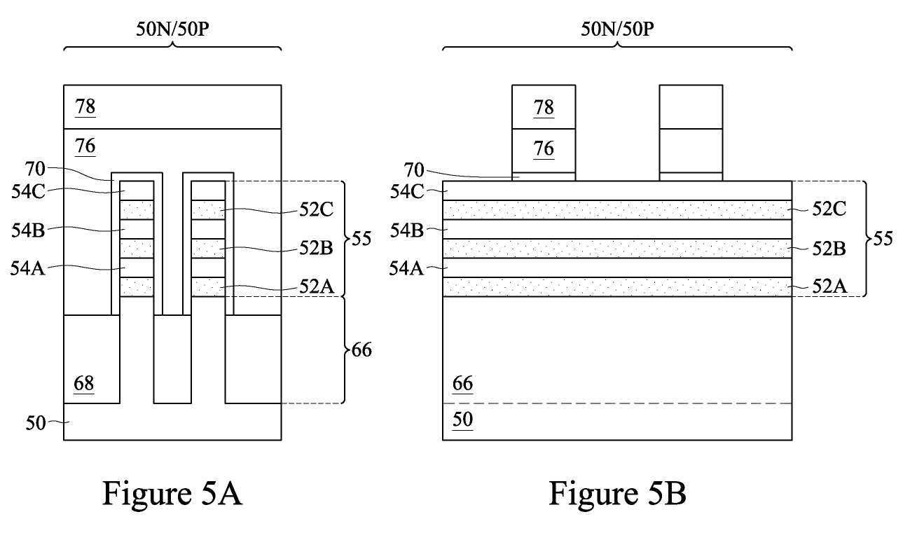

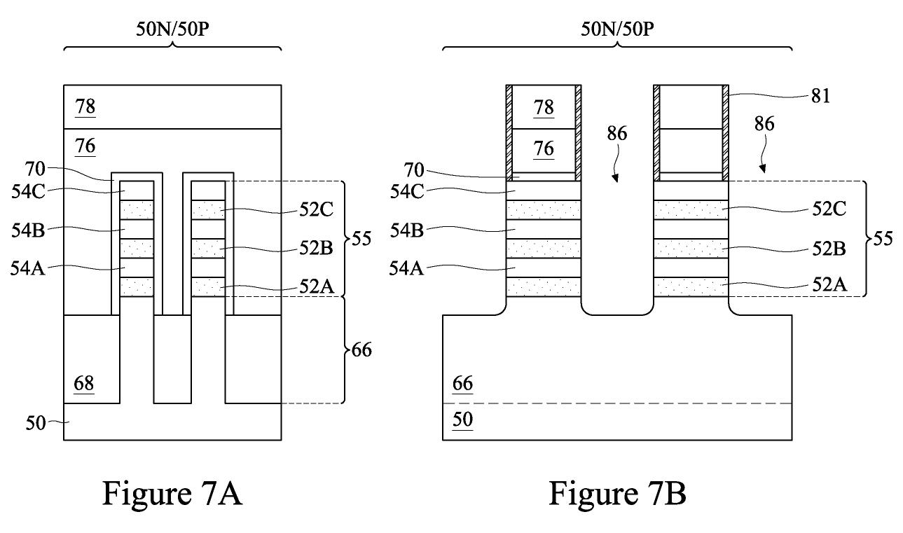

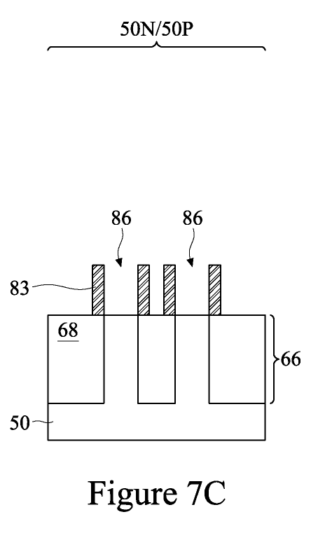

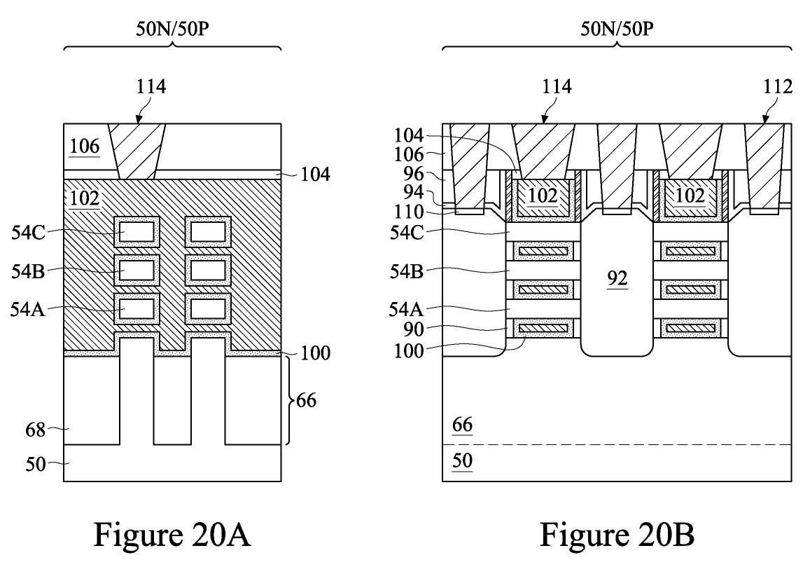

FIGS. 2 through 20 are cross-sectional views of intermediate stages in the manufacturing of nano-FETs, in accordance with some embodiments. FIGS. 3, 4, 5A, 6A, 7A, 8A, 9A, 10A,11A, 11C, 12A, 13A, 14A, 15A, 16A, 17A, 18A, 19A, and FIG. 20A, illustrate reference cross-section A-A’ illustrated in FIG. 1. FIGS. 5B, 6B, 7B, 8B, 9B, 10B, 11B, 11D, 12B-12D, 13B, 14B, 15B, 16B, 17B, 18B, 19B, and FIG. 20B illustrate reference cross-section B-B’ illustrated in FIG. 1. FIGS. 7C, 13C, 13D, 18C, and FIG. 19C, illustrate reference cross-section C-C’ illustrated in FIG. 1.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 has an n-type region 50N and a p-type region 50P. The n-type region 50N can be for forming n-type devices, such as NMOS transistors, e.g., n-type nano-FETs, and the p-type region 50P can be for forming p-type devices, such as PMOS transistors, e.g., p-type nano-FETs. The n-type region 50N may be physically separated from the p-type region 50P (as illustrated by divider 20), and any number of device features (e.g., other active devices, doped regions, isolation structures, etc.) may be disposed between the n-type region 50N and the p-type region 50P. Although one n-type region 50N and one p-type region 50P are illustrated, any number of n-type regions 50N and p-type regions 50P may be provided. Subsequent figures describe processing steps that may be performed in either the n-type regions 50N or the p-type regions 50P unless otherwise noted.

Further in FIG. 2, a multi-layer stack 64 is formed over the substrate 50. The multi-layer stack 64 includes alternating layers of first semiconductor layers 51A-C (collectively referred to as first semiconductor layers 51) and second semiconductor layers 53A-C (collectively referred to as second semiconductor layers 53). For purposes of illustration and as discussed in greater detail below, the first semiconductor layers 51 will be removed and the second semiconductor layers 53 will be patterned to form channel regions of nano-FETs in both the n-type region 50N and the p-type region 50P. Nevertheless, in some embodiments, the second semiconductor layers 53 may be removed and the first semiconductor layers 51 may be patterned to form channel regions of nano-FETs in both the n-type region 50N and the p-type region 50P. For example, the channel regions in both the n-type region 50N and the p-type region 50P may have a same material composition (e.g., silicon, or the another semiconductor material) and be formed simultaneously.

In other embodiments, the first semiconductor layers 51 may be removed and the second semiconductor layers 53 may be patterned to form channel regions of nano-FETs in the p-type region 50P, and the second semiconductor layers 53 may be removed and the first semiconductor layers 51 may be patterned to form channel regions of nano-FETs in the n-type region 50N. In still other embodiments, the first semiconductor layers 51 may be removed and the second semiconductor layers 53 may be patterned to form channel regions of nano-FETs in the n-type region 50N, and the second semiconductor layers 53 may be removed and the first semiconductor layers 51 may be patterned to form channel regions of nano-FETs in the p-type region 50P. In such embodiments, the channel regions of the n-type region 50N may have a different material composition than the channel regions of the p-type region 50P. The first semiconductor layers 51 and the second semiconductor layers 53 may be selectively removed from each of the n-type region 50N and p-type region 50P through additional masking and etching steps. For example, the channel regions of the n-type region 50N may be silicon channel regions while the channel regions of the p-type region 50P may be silicon germanium channel regions.

The multi-layer stack 64 is illustrated as including three layers of each of the first semiconductor layers 51 and the second semiconductor layers 53 for illustrative purposes. In some embodiments, the multi-layer stack 64 may include any number of the first semiconductor layers 51 and the second semiconductor layers 53. Each of the layers of the multi-layer stack 64 may be epitaxially grown using a process such as chemical vapor deposition (CVD), atomic layer deposition (ALD), vapor phase epitaxy (VPE), molecular beam epitaxy (MBE), or the like.

In various embodiments, the first semiconductor layers 51 may be formed of a first semiconductor material, such as silicon germanium, or the like, and the second semiconductor layers 53 may be formed of a second semiconductor material, such as silicon, silicon carbon, or the like. The first semiconductor materials and the second semiconductor materials may be materials having a high-etch selectivity to one another. As such, the first semiconductor layers 51 of the first semiconductor material may be removed without significantly removing the second semiconductor layers 53 of the second semiconductor material, thereby allowing the second semiconductor layers 53 to be patterned to form channel regions of the nano-FETs.

Referring now to FIG. 3, fins 66 are formed in the substrate 50 and nanostructures 55 are formed in the multi-layer stack 64, in accordance with some embodiments. In some embodiments, the nanostructures 55 and the fins 66 may be formed in the multi-layer stack 64 and the substrate 50, respectively, by etching trenches 58 in the multi-layer stack 64 and the substrate 50. The etching may be any acceptable etch process, such as a reactive ion etch (RIE), neutral beam etch (NBE), the like, or a combination thereof. The etching may be anisotropic. During the etching process, a hard mask 56 may be used to define a pattern of the fins 66 and the nanostructures 55. The hard mask 56 may comprise any suitable insulating material, such as an oxide, a nitride, and oxynitride, and oxycarbonitride, or the like. In some embodiments (not separately illustrated), the hard mask 56 may be a multi-layer structure. The hard mask 56 may be formed over the nanostructures 55 using an acceptable process(es) such as thermal oxidation, physical vapor deposition (PVD), CVD, ALD, combinations thereof, or the like.

The fins 66 and the nanostructures 55 may be patterned by any suitable method. For example, the fins 66 and the nanostructures 55 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 66 and the nanostructures 55.

Forming the nanostructures 55 by etching the multi-layer stack 64 may further define first nanostructures 52A-C (collectively referred to as the first nanostructures 52) from the first semiconductor layers 51 and define second nanostructures 54A-C (collectively referred to as the second nanostructures 54) from the second semiconductor layers 53. The first nanostructures 52 and the second nanostructures 54 may further be collectively referred to as the nanostructures 55.

FIG. 3 illustrates the fins 66 having substantially equal widths for illustrative purposes. In some embodiments, widths of the fins 66 in the n-type region 50N may be greater or thinner than the fins 66 in the p-type region 50P. Further, while FIG. 3 illustrates each of the fins 66 and the nanostructures 55 as having a consistent width throughout, in other embodiments, the fins 66 and/or the nanostructures 55 may have tapered sidewalls such that a width of each of the fins 66 and/or the nanostructures 55 continuously increases in a direction towards the substrate 50. In such embodiments, each of the nanostructures 55 may have a different width and be trapezoidal in shape. Still further, a bottom surface of the trenches 58 between the fins 66 may be flat, as illustrated, but may be rounded and include concave and/or convex portions in other embodiments.

In FIG. 4, shallow trench isolation (STI) regions 68 are formed adjacent the fins 66. The STI regions 68 may be formed by depositing an insulation material over the substrate 50, the fins 66, and nanostructures 55, and between adjacent fins 66 to fill the trenches 58. The insulation material may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In the illustrated embodiment, the insulation material is silicon oxide formed by an FCVD process. An anneal process may be performed once the insulation material is formed. In an embodiment, the insulation material is formed such that excess insulation material covers the nanostructures 55. Although the insulation material is illustrated as a single layer, some embodiments may utilize multiple layers. For example, in some embodiments a liner (not separately illustrated) may first be formed along a surface of the substrate 50, the fins 66, and the nanostructures 55. Thereafter, a fill material, such as those discussed above may be formed over the liner.

A removal process is then applied to the insulation material to remove excess insulation material over the nanostructures 55. In some embodiments, a planarization process such as a chemical mechanical polish (CMP), an etch-back process, combinations thereof, or the like may be utilized. The planarization process exposes the nanostructures 55 such that top surfaces of the nanostructures 55 and the insulation material are level after the planarization process is complete.

The insulation material is then recessed to form the STI regions 68. The insulation material is recessed such that upper portions of fins 66 protrude from between neighboring STI regions 68. Further, the top surfaces of the STI regions 68 may have a flat surface as illustrated, a convex surface, a concave surface (such as dishing), or a combination thereof. The top surfaces of the STI regions 68 may be formed flat, convex, and/or concave by an appropriate etch. The STI regions 68 may be recessed using an acceptable etching process, such as one that is selective to the material of the insulation material (e.g., etches the material of the insulation material at a faster rate than the material of the fins 66 and the nanostructures 55). For example, an oxide removal using, for example, dilute hydrofluoric (dHF) acid may be used.

Further in FIG. 4, appropriate wells (not separately illustrated) may be formed in the fins 66 and/or the nanostructures 55. In embodiments with different well types, different implant steps for the n-type region 50N and the p-type region 50P may be achieved using a photoresist or other masks (not separately illustrated). For example, a photoresist may be formed over the fins 66 and the nanostructures 55 in the n-type region 50N and the p-type region 50P. The photoresist is patterned to expose the p-type region 50P. The photoresist can be formed by using a spin-on technique and can be patterned using acceptable photolithography techniques. Once the photoresist is patterned, an n-type impurity implant is performed in the p-type region 50P, and the photoresist may act as a mask to substantially prevent n-type impurities from being implanted into the n-type region 50N. The n-type impurities may be phosphorus, arsenic, antimony, or the like implanted in the region to a concentration in a range from about 10¹³ atoms/cm³ to about 10¹⁴ atoms/cm³. After the implant, the photoresist is removed, such as by an acceptable ashing process.

Following or prior to the implanting of the p-type region 50P, a photoresist or other masks (not separately illustrated) is formed over the fins 66 and the nanostructures 55 in the p-type region 50P and the n-type region 50N. The photoresist is patterned to expose the n-type region 50N. The photoresist can be formed by using a spin-on technique and can be patterned using acceptable photolithography techniques. Once the photoresist is patterned, a p-type impurity implant may be performed in the n-type region 50N, and the photoresist may act as a mask to substantially prevent p-type impurities from being implanted into the p-type region 50P. The p-type impurities may be boron, boron fluoride, indium, or the like implanted in the region to a concentration in a range from about 10¹³ atoms/cm³ to about 10¹⁴ atoms/cm³. After the implant, the photoresist may be removed, such as by an acceptable ashing process.

After the implants of the n-type region 50N and the p-type region 50P, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

In FIGS. 5A and 5B, dummy gates are formed over and along sidewalls of the nanostructures 55 and the fin 66. To form the dummy gates, first, a dummy dielectric layer is formed on the fins 66 and/or the nanostructures 55. The dummy dielectric layer may be, for example, silicon oxide, silicon nitride, a combination thereof, or the like, and may be deposited or thermally grown according to acceptable techniques. A dummy gate layer is formed over the dummy dielectric layer, and a mask layer is formed over the dummy gate layer. The dummy gate layer may be deposited over the dummy dielectric layer and then planarized, such as by a CMP. The mask layer may be deposited over the dummy gate layer. The dummy gate layer may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer may be deposited by physical vapor deposition (PVD), CVD, sputter deposition, or other techniques for depositing the selected material. The dummy gate layer may be made of other materials that have a high etching selectivity from the etching of isolation regions. The mask layer may include, for example, silicon nitride, silicon oxynitride, or the like.

Subsequently, the mask layer may be patterned using acceptable photolithography and etching techniques to form masks 78. The pattern of the masks 78 then may be transferred to the dummy gate layer and to the dummy dielectric layer to form dummy gates 76 and dummy gate dielectrics 70, respectively. The dummy gates 76 cover respective channel regions of the fins 66. The pattern of the masks 78 may be used to physically separate each of the dummy gates 76 from adjacent dummy gates 76. The dummy gates 76 may also have a lengthwise direction substantially perpendicular to the lengthwise direction of respective fins 66. It is noted that the dummy gate dielectrics 70 is shown covering only the fins 66 and the nanostructures 55 for illustrative purposes only. In some embodiments, the dummy gate dielectrics 70 may be deposited such that the dummy gate dielectrics 70 covers the STI regions 68, such that the dummy gate dielectrics 70 extends between the dummy gates 76 and the STI regions 68.

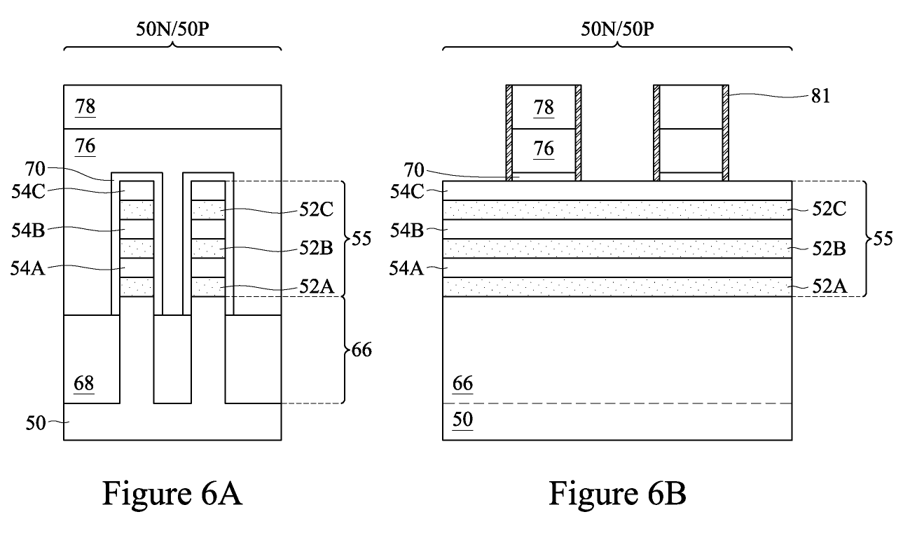

In FIGS. 6A and 6B, gate spacers 81 (shown in FIG. 6B) are formed over the nanostructures 55 and the STI regions 68, on exposed sidewalls of the masks 78 (if present), the dummy gates 76, and the dummy gate dielectrics 70. The gate spacers 81 may be formed by conformally forming one or more dielectric material(s) and subsequently etching the dielectric material(s). Acceptable dielectric materials may include silicon oxide, silicon nitride, silicon oxynitride, silicon oxycarbonitride, or the like, which may be formed by a deposition process such as chemical vapor deposition (CVD), atomic layer deposition (ALD), or the like. Other insulation materials formed by any acceptable process may be used. Any acceptable etch process, such as a dry etch, a wet etch, the like, or a combination thereof, may be performed to pattern the dielectric material(s). The etching may be anisotropic. The dielectric material(s), when etched, have portions left on the sidewalls of the dummy gates 76 (thus forming the gate spacers 81). As subsequently described in greater detail, the dielectric material(s), when etched, may also have portions left on the sidewalls of the semiconductor fins 66 and/or the nanostructures 55 (thus forming fin spacers 83, see FIG. 7C). After etching, the fin spacers 83 and/or the gate spacers 81 can have straight sidewalls (as illustrated) or can have curved sidewalls (not separately illustrated).

Further, implants for lightly doped source/drain (LDD) regions (not separately illustrated) may be performed. The LDD implants may be performed before the gate spacers 81 are formed. In embodiments with different device types, similar to the implants for the previously described wells, a mask, such as a photoresist, may be formed over the n-type region 50N, while exposing the p-type region 50P, and appropriate type (e.g., p-type) impurities may be implanted into the semiconductor fins 66 and the nanostructures 55 exposed in the p-type region 50P. The mask may then be removed. Subsequently, a mask, such as a photoresist, may be formed over the p-type region 50P while exposing the n-type region 50N, and appropriate type impurities (e.g., n-type) may be implanted into the semiconductor fins 66 and the nanostructures 55 exposed in the n-type region 50N. The mask may then be removed. The n-type impurities may be the any of the n-type impurities previously discussed, and the p-type impurities may be the any of the p-type impurities previously discussed. The lightly doped source/drain regions may have a concentration of impurities in a range from 10¹⁵ atoms/cm³ to 10¹⁹ atoms/cm³. An anneal may be used to repair implant damage and to activate the implanted impurities.

It is noted that the previous disclosure generally describes a process of forming spacers and LDD regions. Other processes and sequences may be used. For example, fewer or additional spacers may be utilized, different sequence of steps may be utilized, additional spacers may be formed and removed, and/or the like. Furthermore, the n-type devices and the p-type devices may be formed using different structures and steps.

In FIGS. 7A-7C, first recesses 86 are formed in the fins 66, the nanostructures 55, and the substrate 50, in accordance with some embodiments. Source drain regions, including but not limited to the epitaxial source/drain regions described herein will be subsequently formed in the first recesses 86. The first recesses 86 may extend through the first nanostructures 52 and the second nanostructures 54, and into the fins 66. As illustrated in FIG. 7C, top surfaces of the STI regions 68 may be level with bottom surfaces of the first recesses 86. In other embodiments, the fins 66 may be etched such that bottom surfaces of the first recesses 86 are disposed above or below the top surfaces of the STI regions 68. The first recesses 86 may be formed by etching the fins 66 and the nanostructures 55 using anisotropic etching processes, such as RIE, NBE, or the like. The gate spacers 81, the fin spacers 83, and the masks 78 mask portions of the fins 66, the nanostructures 55, and the substrate 50 during the etching processes used to form the first recesses 86. A single etch process or multiple etch processes may be used to etch each layer of the nanostructures 55 and/or the fins 66. Timed etch processes may be used to stop the etching of the first recesses 86 after the first recesses 86 reach a desired depth.

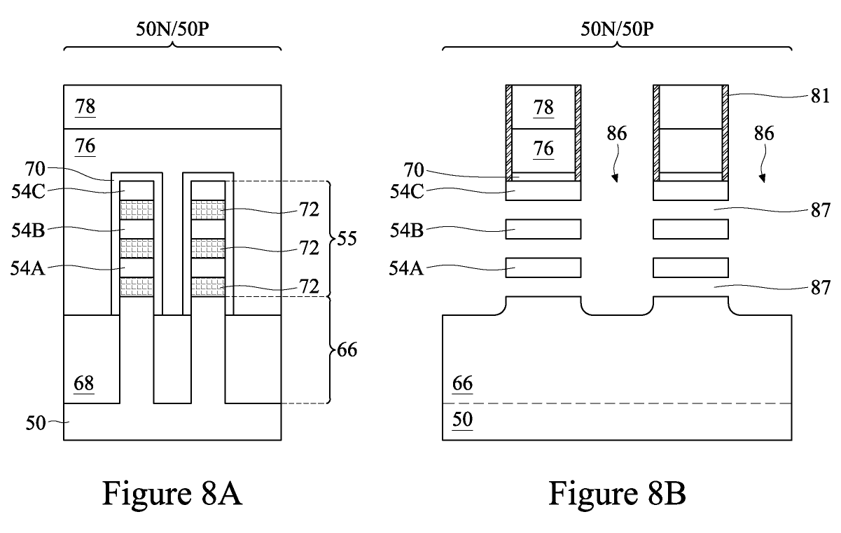

In FIGS. 8A-10B, the first nanostructures 52 are replaced with a sacrificial material (also referred to as disposable oxide interposers (DOI)). Replacing the first nanostructures 52 with sacrificial material may reduce or prevent defects from forming on surfaces of the second nanostructures 54 adjacent the first nanostructures 52 during subsequent annealing processes. Replacing the first nanostructures 52 may include etching away the first nanostructures 52 using a suitable etch process, such as an isotropic etch process, that is performed through the first recesses 86 as illustrated by FIGS. 8A-8B. The etch process may be selective to the material of the first nanostructures 52 and remove the first nanostructures 52 without significantly removing the second nanostructures 54 or the semiconductor fins 66. In an embodiment in which the first nanostructures 52 include, e.g., SiGe, and the second nanostructures 54 include, e.g., Si or SiC, a dry etch process with tetramethylammonium hydroxide (TMAH), ammonium hydroxide (NH₄OH), or the like may be used to remove the first nanostructures 52.

In subsequent process steps, a sacrificial material layer is deposited in the voids 87 left by the removal of first nanostructures 52 (see FIG. 8B). As a consequence of depositing the sacrificial material layer in voids 87, sacrificial material layer will also be deposited elsewhere, such as along the bottoms of recesses 86. This extraneous sacrificial material layer can adversely impact subsequent process steps, critical dimensions of subsequently formed structures, and/or device performance. Similarly, if the extraneous sacrificial material layer is formed on the exposed sides of second nanostructures 54, this extraneous layer can also damage the second nanostructures 54 and likewise adversely impact subsequent process steps, critical dimensions of subsequently formed structures, and/or device performance. Hence, in general terms, embodiments described herein provide a way to treat exposed surfaces of fins 66 and/or sidewalls of second nanostructures 54 to make those exposed surfaces less susceptible to the deposition of a sacrificial material layer thereon.

More specifically, embodiments will be described wherein silicon oxide is deposited as the sacrificial material layer and a nitrogen-containing plasma is employed to treat exposed surfaces of the fins 66 and sidewalls of the second nanostructures 54. While the contemplated embodiments are not limited to using silicon oxide as the sacrificial material layer, the following described embodiments use silicon oxide as a representative sacrificial material layer. Silicon oxide offers the advantages of being a commonly used material in semiconductor processes, with controllable deposition techniques, and offers a high degree of etch selectivity relative to second nanostructures 54 and fins 66. Generally, and as described in greater detail below, silicon oxide can be deposited with good coverage to fill the voids 87, although other sacrificial materials are within the contemplated scope of the present disclosure.

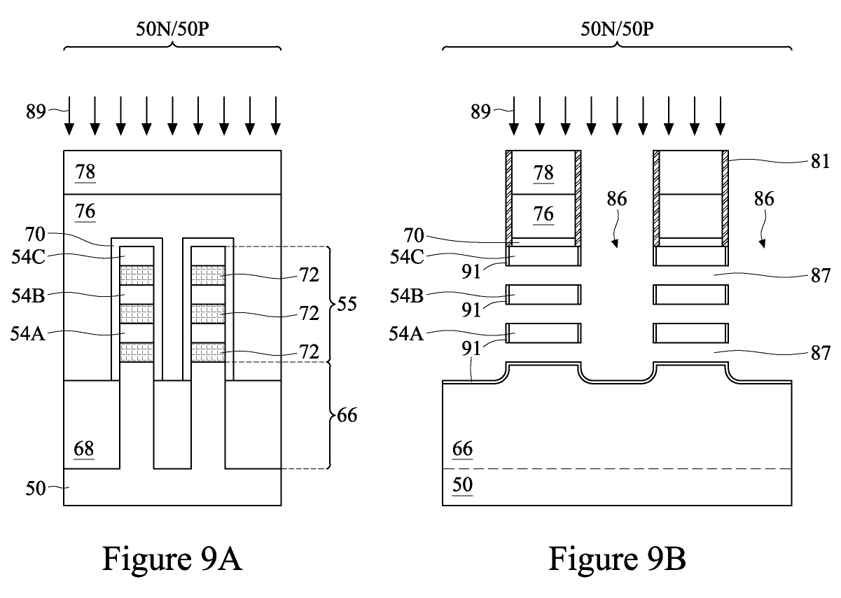

FIGS. 9A and 9B illustrate an embodiment whereby the formation of extraneous silicon oxide (or another sacrificial material layer) is eliminated or significantly reduced by a treatment process that is performed prior to depositing the sacrificial material. Specifically, FIGS. 9A and 9B illustrate a process for treating exposed surface of fins 66 (which form the bottoms of recesses 86) and sidewalls of second nanostructures 54 to make those exposed surfaces less susceptible to formation of a sacrificial material layer on the exposed surfaces. In one contemplated embodiment, the treatment process is a nitrogen-containing plasma treatment 89 performed on exposed surfaces of fins 66. While not being limited to any underlying theory, it is believed that the nitrogen-containing plasma treatment will make the exposed surfaces of fins 66 more hydrophobic, by way of having hydrogen-passivated dangling bonds, which in turn lessens the surface tension between the treated surfaces of fins 66 and the precursor material used to deposit the silicon oxide sacrificial material. The results of the plasma treatment are schematically illustrated by treated surface regions 91 of fins 66 and respective second nanostructures 54. While FIG. 9B schematically illustrates treated surfaces 91, sometimes referred to as modified surfaces 91, the treated surfaces 91 do not necessarily look different or form a detectable interface with the remainder of fins 66 and second nanostructures 54, respectively.

Due to the directional nature of plasma treatment 89, only the sidewalls of second nanostructures 54 are treated. Top and bottom surfaces of the respective second nanostructures 54 are shielded from the plasma treatment (at least substantially so) by the presence of overlying structures. For instance, second nanostructure 54C is shielded by the presence of mask 78, dummy gate 76, and spacers 81 overlying second nanostructure 54C, second nanostructure 54B is likewise shielded by the presence of mask 78, dummy gate 76, and spacers 81, as well as second nanostructure 54C overlying it, and second nanostructure 54A is shielded by the presence of mask 78, dummy gate 76, and spacers 81 , as well as second nanostructure 54C and second nanostructure 54B overlying second nanostructure 54A. As a result, the top and bottom surfaces of second nanostructures 54 are not treated by the above-described treatment process.

As an example, plasma treatment 89 may involve flowing NH₃ at a rate of about 200 sccm (although one skilled in the art will recognize a wide range of flow rate can be involved, depending upon other process conditions, as is readily within the skill of those in the art combined with routine experimentation, once informed by the present disclosure), generating a plasma using RF power in the range of 20 - 150 Watts, and at a pressure in the range of 40 – 120 Pascals, at a temperature in the range of about 100C to about 300C, preferably at a temperature less than 200C. It is contemplated that duration in the range of a few seconds to up to about 10 minutes should be sufficient to treat the relevant surfaces. In other embodiments, a thermal treatment could be employed in lieu of or in conjunction with the above described (or other) plasma process. One skilled in the art will recognize variations and modifications to this exemplary process, through routine experimentation, once informed by the teaching of this disclosure.

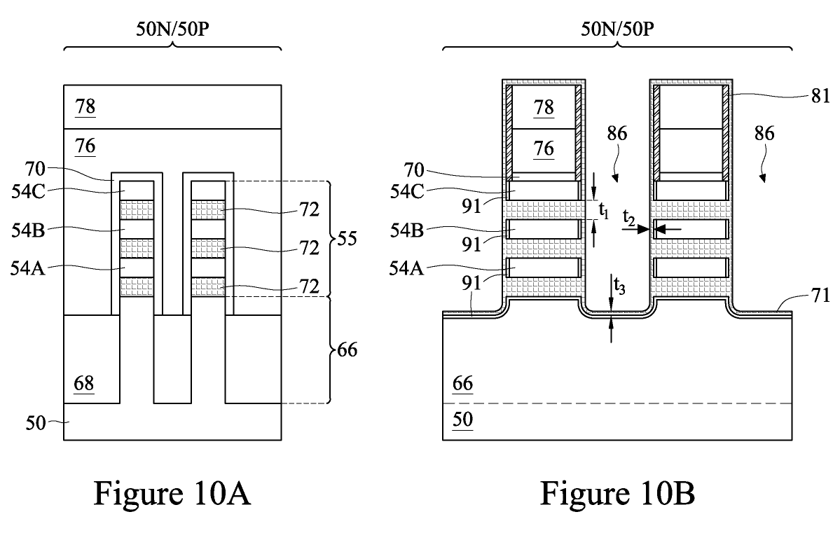

Subsequently, a sacrificial material layer 71 is deposited through the recesses 86 into voids 87, being the spaces where the first nanostructures 52 were removed, as illustrated by FIGS. 10A and 10B. The sacrificial material layer 71 may be deposited by a conformal deposition process, such as CVD, ALD, or the like. In a particularly advantageous embodiment, sacrificial material layer 71 is deposited using a flowable chemical vapor deposition (FCVD) process, which provides good gap fill coverage. This means that the FCVD process effectively fills voids 87 (being the spaces or gaps between respective second nanostructures 54 and between bottom second nanostructures 54A and the underlying fins 66) with sacrificial material layer 71. As a result of the treatment process, such as nitrogen-containing plasma treatment 89 (FIGS. 9A and 9B), little of sacrificial material layer 71 is deposited on the sidewalls of second nanostructures 54 and on the surfaces of fins 66. More particularly, with reference to FIG. 10B, sacrificial material layer 71 is deposited between the untreated stop surface of second nanostructure 54A and the untreated bottom surface of second nanostructure 54B to a thickness of t₁, the value of t₁ being equal to the distance between vertically adjacent second nanostructures 54, for instance, whereas sacrificial material layer 71 is deposited on the treated sidewalls of second nanostructures 54 only to a thickness of t₂ and is deposited on the treated surface of fins 66 to a thickness of t₃, with both t₂ and t₃ being less than the thickness of t₁. In an ideal scenario, both t₂ and t₃ will have a value of zero, meaning that no sacrificial material layer 71 is deposited on the sidewalls of second nanostructures 54 and fins 66. While such a scenario is ideal, it is not necessary in order to achieve the advantages of the illustrated embodiments, as explained more fully below, however.

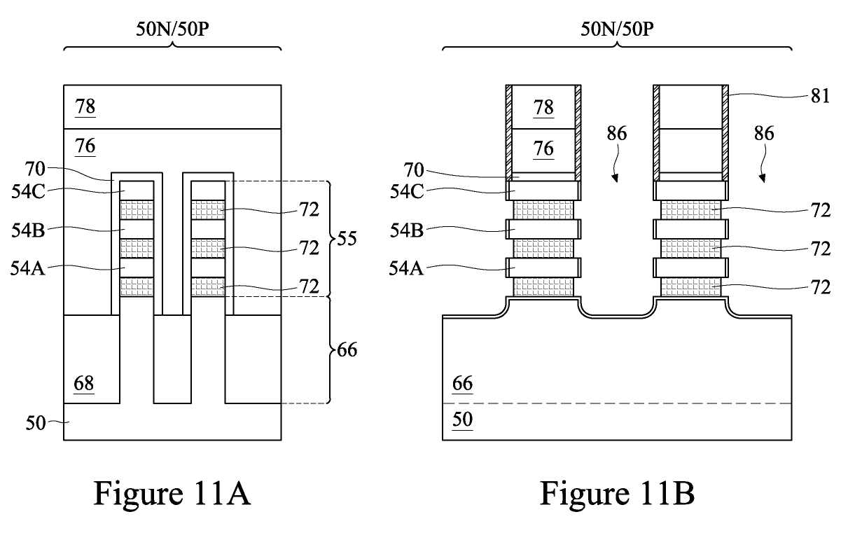

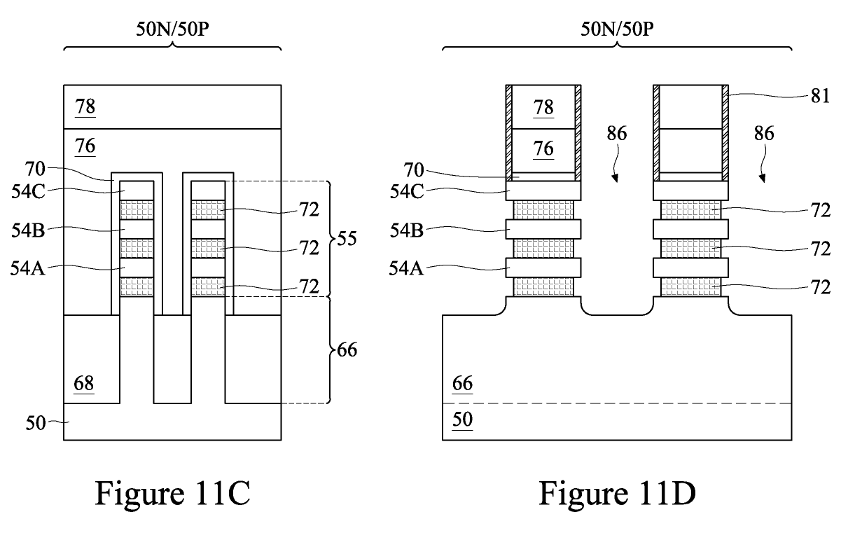

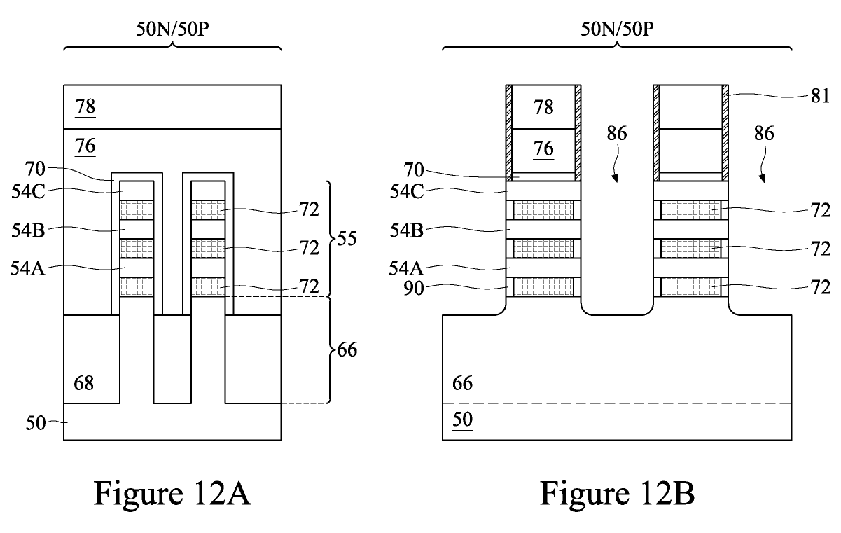

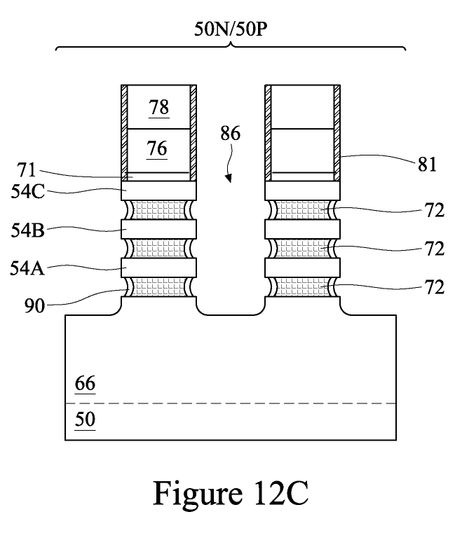

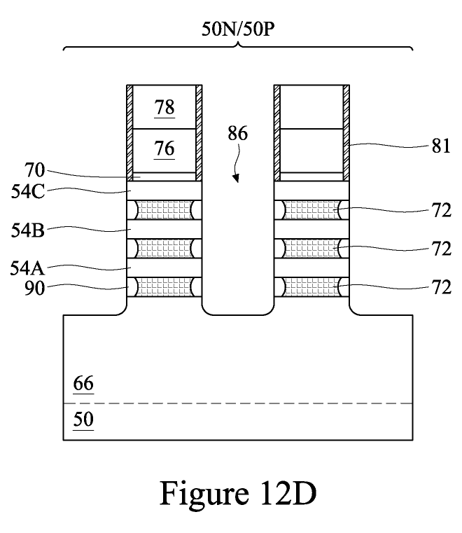

In FIGS. 11A-11B, the sacrificial material layer 71 may then be etched back to form the sacrificial material 72. The etching may be isotropic or anisotropic. For example, the sacrificial material layer 71 may be etched by a wet etch process using diluted HF, or the like as an etchant. In some embodiments, the etching is performed until sidewalls of the sacrificial material layer 71 is recessed past sidewalls of the second nanostructures 54 to form the resulting sacrificial material 72 shown in FIG. 11B. Although sidewalls of sacrificial material 72 are illustrated as being straight in FIG. 11B, the sidewalls may be concave or convex (see e.g., FIG. 12C). As FIG. 11B also illustrates, the etch back process removes those portions of sacrificial material layer 71, if any, that were deposited on sidewalls of second nanostructures 54 and on fins 66. If sacrificial material layer 71 had been deposited on the sidewalls of second nanostructures 54 and on fins 66 to the thickness t₁, it is likely that some residual amount of sacrificial material layer 71 would remain on those surfaces. As addressed above, such remaining residual portion of sacrificial material layer 71 on the sidewalls of second nanostructures 54 and on fins 66 can negatively impact subsequent process steps and device performance. By performing the above-described treatment process to make sidewalls of second nanostructures 54 and on fins 66 less susceptible to deposition of sacrificial material layer 71, those surfaces can be free of any residual sacrificial material layer 71 after the etch back process.

Replacing the first nanostructures 52 with the sacrificial material 72 may provide advantages. For example, in subsequent source/drain formation steps, one or more high temperature processes may be performed to, for example, activate the dopants in the source/drain regions. When the material of the first nanostructures 52 (e.g., SiGe) is exposed to high temperatures, germanium intermixing and increased roughness at an interface between the nanostructures 52 and 54 may result. Such manufacturing defects may degrade the performance of the resulting transistor devices. For example, when germanium diffuses into the second nanostructures 54, germanium residue may remain in channel regions of the resulting transistor devices, which negatively affects the performance of the channel regions. By replacing the first nanostructures 52 with an insulating material prior to the high temperature processes (e.g., source/drain annealing), manufacturing defects can be reduced and device performance can be improved (e.g., increased current drive, reduced capacitance, and improved short channel effect). By ensuring that sacrificial material layer 71 is completely, or substantially completely, removed from the sidewalls of second nanostructures 54 and fins 66, complications that might otherwise arise from the formation of sacrificial material 72 can be eliminated or reduced to acceptable levels.

Subsequent to the etch back process described above, a baking process may be performed, whereby the device is subject to an elevated temperature in the range of from about 300C to about 400C, for a period of from about 15 minutes to about 30 minutes, with an inert environment, such as argon, at a pressure in the range of around 100 torr, as an example. Other baking process conditions and parameters will be apparent to those skilled in the art, using routine experimentation once informed by the present disclosure. It is contemplated that a wet clean process could be employed in lieu of a baking process, although care must be taken to ensure that the wet clean process does not negatively impact the surface bond condition of the treated surfaces. After the baking process (or other treatment process), the surfaces of the sidewalls of second nanostructures 54 and fins 66 are returned to their pre-treatment state, as shown by the absence of treated surfaces 91 in FIGS. 11C and 11D. In other embodiments, the baking process can occur before the etch back process or can occur at some later state in the process flow, such as after inner spacers are formed, as described below.

Although the baking process may return the treated surface to their prior state, in terms of susceptibility to deposition, hydrophobic nature, etc., is some embodiments, artifacts of the plasma treatment 89 may remain. For instance, when an NH₃ plasma treatment is used, trace amounts of nitrogen may remain on the treated surfaces of the second nanostructures 54 and the fin 66, even after a baking process is employed. It is contemplated, for instance, that a mole percentage ratio of nitrogen to silicon at the (post-bake) treated surface of the fin could be in a range of up to 0.1:1 in some embodiments. The presence of these trace amounts of nitrogen will not adversely impact the resulting structure, in most contemplated embodiments.

In FIGS. 12A and 12B, inner spacers 90 are formed in the recesses 86 on the sidewalls of the sacrificial material 72. The inner spacers 90 act as isolation features between subsequently formed source/drain regions and a gate structure. As will be discussed in greater detail below, source/drain regions will be formed in the recesses 86, while the sacrificial material 72 will be replaced with corresponding gate structures. The inner spacers 90 may also be used to prevent damage to subsequently formed source/drain regions by subsequent etching processes, such as etching processes used to form gate structures.

The inner spacers 90 may be formed by depositing an inner spacer layer (not separately illustrated) over the structures illustrated in FIGS. 11C and 11D (or the structures illustrated in FIGS. 11A and 11B if the above-described baking process is deferred until a later stage in the process flow). The inner spacer layer may be deposited by a conformal deposition process, such as CVD, ALD, or the like. The inner spacer layer may comprise a material such as silicon nitride or silicon oxynitride, although any suitable material, such as low-dielectric constant (low-k) materials having a k-value less than about 3.5, may be utilized. The inner spacer layer may then be anisotropically etched to form the inner spacers 90. The inner spacer layer may be etched by an anisotropic etching process, such as RIE, NBE, or the like.

Although outer sidewalls of the inner spacers 90 are illustrated as being flush with sidewalls of the second nanostructures 54, the outer sidewalls of the inner spacers 90 may extend beyond or be recessed from sidewalls of the second nanostructures 54 (see e.g., FIG. 12C). Moreover, although the outer sidewalls of the inner spacers 90 are illustrated as being straight in FIG. 12B, the outer sidewalls of the inner spacers 90 may be concave or convex. As an example, FIG. 12C illustrates an embodiment in which sidewalls of the sacrificial material 72 are concave, outer sidewalls of the inner spacers 90 are concave, and the inner spacers 90 are recessed from sidewalls of the second nanostructures 54. Other configurations are also possible. For example, FIG. 12D illustrates an embodiment in which sidewalls of the sacrificial material 72 are concave, outer sidewalls of the inner spacers 90 are straight, and the inner spacers 90 are flush with sidewalls of the second nanostructures 54.

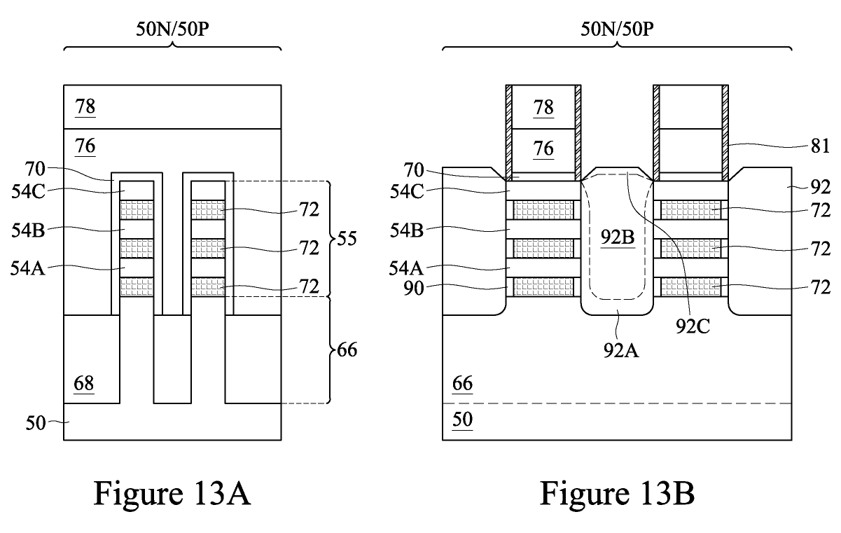

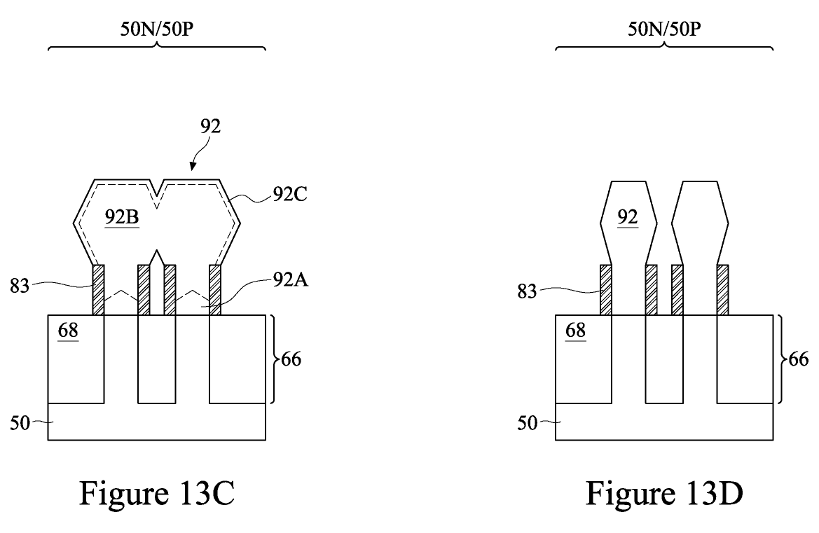

In FIGS. 13A-13D, epitaxial source/drain regions 92 are formed in the first recesses 86. Note that because of the above-described treatment process (see FIGS. 9A and 9B), the bottom of recesses 86 are completely free, or at least substantially free, of any residual sacrificial material layer 71 (see FIG. 10B) that might otherwise impact or interfere with the epitaxial growth process for forming source/drain regions 92. In some embodiments, the source/drain regions 92 may exert stress on the second nanostructures 54 in the n-type region 50N and/or on the second nanostructures 54 in the p-type region 50P, thereby improving performance. As illustrated in FIG. 13B, the epitaxial source/drain regions 92 are formed in the first recesses 86 such that each dummy gate 76 is disposed between respective neighboring pairs of the epitaxial source/drain regions 92. In some embodiments, the gate spacers 81 are used to separate the epitaxial source/drain regions 92 from the dummy gates 76 and the inner spacers 90 are used to separate the epitaxial source/drain regions 92 from the sacrificial material 72 by an appropriate lateral distance so that the epitaxial source/drain regions 92 do not short out with subsequently formed gates of the resulting nano-FETs.

The epitaxial source/drain regions 92 in the n-type region 50N, e.g., the NMOS region, may be formed by masking the p-type region 50P, e.g., the PMOS region. Then, the epitaxial source/drain regions 92 are epitaxially grown in the first recesses 86 in the n-type region 50N. The epitaxial source/drain regions 92 may include any acceptable material appropriate for n-type nano-FETs. For example, if the second nanostructures 54 are silicon, the epitaxial source/drain regions 92 in the n-type region 50N may include materials exerting a tensile strain on the second nanostructures 54, such as silicon, silicon carbide, phosphorous doped silicon carbide, silicon phosphide, or the like.

The epitaxial source/drain regions 92 in the p-type region 50P, e.g., the PMOS region, may be formed by masking the n-type region 50N, e.g., the NMOS region. Then, the epitaxial source/drain regions 92 are epitaxially grown in the first recesses 86 in the p-type region 50P. The epitaxial source/drain regions 92 may include any acceptable material appropriate for p-type nano-FETs. For example, if the second nanostructures 54 are silicon, the epitaxial source/drain regions 92 in the p-type region 50P may include materials exerting a compressive strain on the second nanostructures 54, such as silicon-germanium, boron doped silicon-germanium, germanium, germanium tin, or the like.

The epitaxial source/drain regions 92, the second nanostructures 54, and/or the substrate 50 may be implanted with dopants to form source/drain regions, similar to the process previously discussed for forming lightly-doped source/drain regions, followed by an anneal. The source/drain regions may have an impurity concentration of between about 1x10¹⁹ atoms/cm³ and about 1x10²¹ atoms/cm³. The n-type and/or p-type impurities for source/drain regions may be any of the impurities previously discussed. In some embodiments, the epitaxial source/drain regions 92 may be in situ doped during growth.

As a result of the epitaxy processes used to form the epitaxial source/drain regions 92 in the n-type region 50N and the p-type region 50P, upper surfaces of the epitaxial source/drain regions 92 have facets which expand laterally outward beyond sidewalls of the nanostructures 55. In some embodiments, these facets cause adjacent epitaxial source/drain regions 92 of a same nano-FET to merge as illustrated by FIG. 13C. In other embodiments, adjacent epitaxial source/drain regions 92 remain separated after the epitaxy process is completed as illustrated by FIG. 13D. In the embodiments illustrated in FIGS. 13C and 13D, the fin spacers 83 may be formed on top surfaces of the STI regions 68, thereby blocking the epitaxial growth. In some other embodiments, the fin spacers 83 may cover portions of the sidewalls of the nanostructures 55 further blocking the epitaxial growth. In some other embodiments, the spacer etch used to form the fin spacers 83 may be adjusted to remove the spacer material to allow the epitaxially grown region to extend to the surface of the STI structures 68.

The epitaxial source/drain regions 92 may comprise one or more semiconductor material layers. For example, the epitaxial source/drain regions 92 may comprise a first semiconductor material layer 92A, a second semiconductor material layer 92B, and a third semiconductor material layer 92C. Any number of semiconductor material layers may be used for the epitaxial source/drain regions 92. Each of the first semiconductor material layer 92A, the second semiconductor material layer 92B, and the third semiconductor material layer 92C may be formed of different semiconductor materials and may be doped to different dopant concentrations. In some embodiments, the first semiconductor material layer 92A may have a dopant concentration less than the second semiconductor material layer 92B and greater than the third semiconductor material layer 92C. In embodiments in which the epitaxial source/drain regions 92 comprise three semiconductor material layers, the first semiconductor material layer 92A may be deposited, the second semiconductor material layer 92B may be deposited over the first semiconductor material layer 92A, and the third semiconductor material layer 92C may be deposited over the second semiconductor material layer 92B.

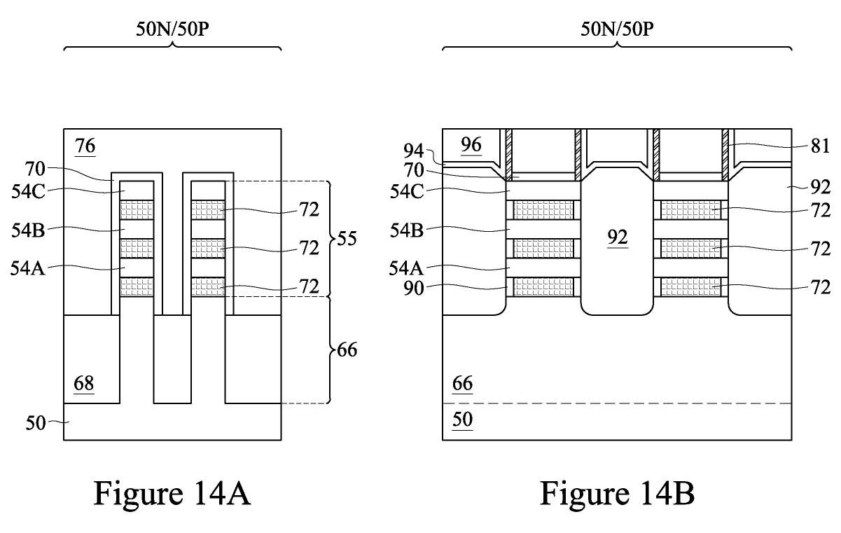

In FIGS. 14A and 14B, a first interlayer dielectric (ILD) 96 is deposited over the structure. The first ILD 96 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 94 is disposed between the first ILD 96 and the epitaxial source/drain regions 92, the masks 78 (illustrated in FIGS. 13A and 13B), and the gate spacers 81. The CESL 94 may comprise a dielectric material, such as, silicon nitride, silicon oxide, silicon oxynitride, or the like, having a different etch rate than the material of the overlying first ILD 96.

After the first ILD 96 is deposited, a planarization process, such as a CMP, may be performed to level the top surface of the first ILD 96 with the top surfaces of the dummy gates 76 or the masks 78. The planarization process may also remove the masks 78 on the dummy gates 76, and portions of the gate spacers 81 along sidewalls of the masks 78. After the planarization process, top surfaces of the dummy gates 76, the gate spacers 81, and the first ILD 96 are level within process variations, as illustrated in FIG. 14B. Accordingly, the top surfaces of the dummy gates 76 are exposed through the first ILD 96. In some embodiments, the masks 78 may remain, in which case the planarization process levels the top surface of the first ILD 96 with top surface of the masks 78 and the gate spacers 81.

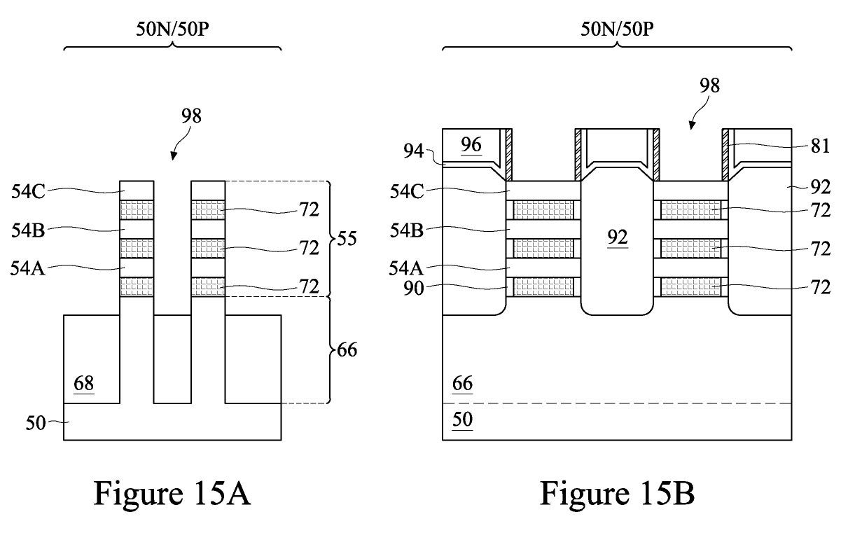

In FIGS. 15A and 15B, the dummy gates 76, and the masks 78 if present, are removed in one or more etching steps, so that second recesses 98 are formed. Portions of the dummy gate dielectrics 70 may also be removed. In some embodiments, the dummy gates 76 and the dummy gate dielectrics 70 are removed by an anisotropic dry etch process. For example, the etching process may include a dry etch process using reaction gas(es) that selectively etch the dummy gates 76 at a faster rate than the first ILD 96 or the gate spacers 81. Each second recess 98 exposes and/or overlies portions of nanostructures 55, which act as channel regions in subsequently completed nano-FETs. Portions of the nanostructures 55 which act as the channel regions are disposed between neighboring pairs of the epitaxial source/drain regions 92. During the removal, the dummy gate dielectrics 70 may be used as etch stop layers when the dummy gates 76 are etched. The dummy gate dielectrics 70 may then be removed after the removal of the dummy gates 76.

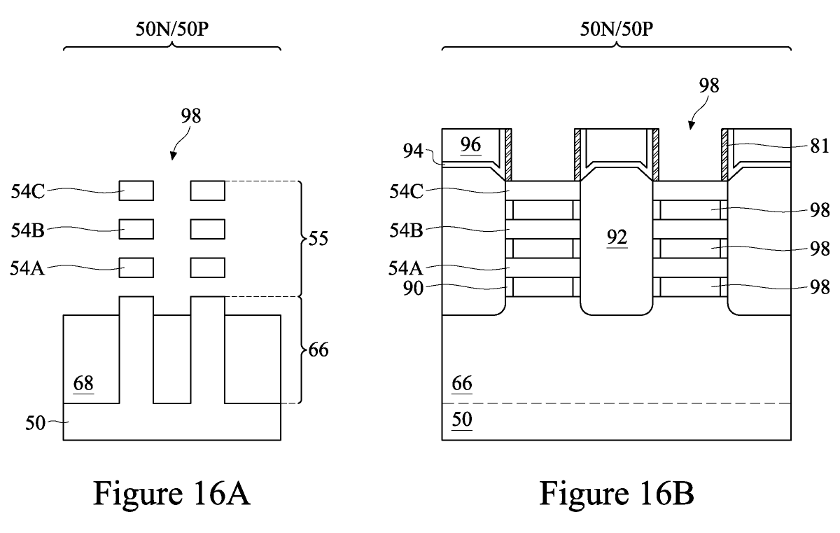

In FIGS. 16A and 16B, the sacrificial material 72 is removed, extending the second recesses 98. Removing the sacrificial material 72 may include performing an isotropic etching process such as wet etching or the like using etchants which are selective to the materials of the sacrificial material 72, while the second nanostructures 54 remain relatively unetched as compared to the sacrificial material 72. The sacrificial material 72 may be completely removed, or a residue of the sacrificial material 72 may remain on sidewalls of the inner spacers in the second recesses 98 (see e.g., FIG. 15C).

In some embodiments, the STI regions 68 may be etched while removing the sacrificial material 72, but the total amount of loss in the STI regions 68 may be reduced by controlling etching parameters (e.g., timing) while removing the sacrificial material 72. In other embodiments, the STI regions 68 may include a hard mask (not separately illustrated) at a top surface to protect the underlying STI regions 68 from etching while patterning and removing the sacrificial material 72. In such embodiments, the hard mask may comprise, for example, a nitride.

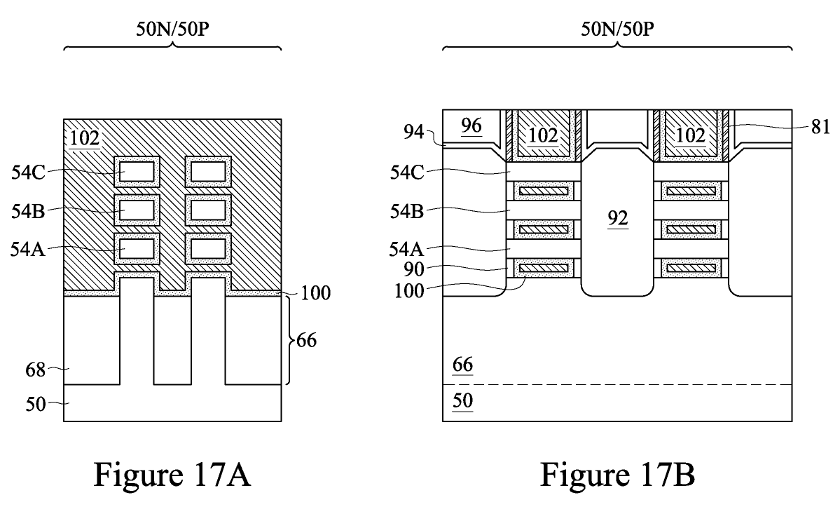

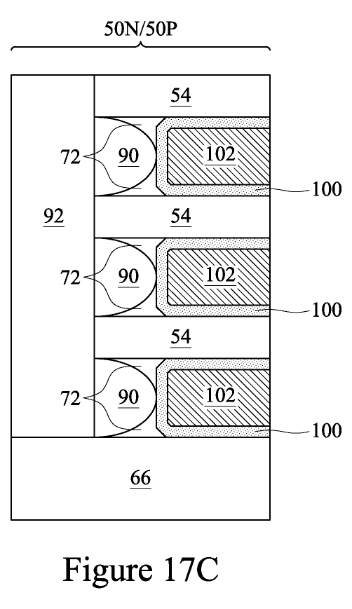

In FIGS. 17A-17C, gate dielectric layers 100 and gate electrodes 102 are formed for replacement gates. The gate dielectric layers 100 are deposited conformally in the second recesses 98. The gate dielectric layers 100 may be formed on top surfaces and sidewalls of the substrate 50 and on top surfaces, sidewalls, and bottom surfaces of the second nanostructures 54. The gate dielectric layers 100 may also be deposited on top surfaces of the first ILD 96, the CESL 94, the gate spacers 81, and the STI regions 68.

In accordance with some embodiments, the gate dielectric layers 100 comprise one or more dielectric layers, such as an oxide, a metal oxide, an interfacial layer, the like, or combinations thereof. For example, in some embodiments, the gate dielectrics may comprise a silicon oxide layer and a metal oxide layer over the silicon oxide layer. In some embodiments, the gate dielectric layers 100 include a high-k dielectric material, and in these embodiments, the gate dielectric layers 100 may have a k value greater than about 7.0, and may include a metal oxide or a silicate of hafnium, aluminum, zirconium, lanthanum, manganese, barium, titanium, lead, and combinations thereof. The structure of the gate dielectric layers 100 may be the same or different in the n-type region 50N and the p-type region 50P. The formation methods of the gate dielectric layers 100 may include molecular-beam deposition (MBD), ALD, PECVD, and the like.

The gate electrodes 102 are deposited over the gate dielectric layers 100, respectively, and fill the remaining portions of the second recesses 98. The gate electrodes 102 may include a metal-containing material such as titanium nitride, titanium oxide, tantalum nitride, tantalum carbide, cobalt, ruthenium, aluminum, tungsten, combinations thereof, or multi-layers thereof. For example, although single layer gate electrodes 102 are illustrated in FIGS. 17A-17C, the gate electrodes 102 may comprise any number of liner layers, any number of work function tuning layers, and a fill material. Any combination of the layers which make up the gate electrodes 102 may be deposited in the n-type region 50N between adjacent ones of the second nanostructures 54 and between the second nanostructure 54A and the substrate 50, and may be deposited in the p-type region 50P between adjacent ones of the second nanostructures 54.

The formation of the gate dielectric layers 100 in the n-type region 50N and the p-type region 50P may occur simultaneously such that the gate dielectric layers 100 in each region are formed from the same materials, and the formation of the gate electrodes 102 may occur simultaneously such that the gate electrodes 102 in each region are formed from the same materials. In some embodiments, the gate dielectric layers 100 in each region may be formed by distinct processes, such that the gate dielectric layers 100 may be different materials and/or have a different number of layers, and/or the gate electrodes 102 in each region may be formed by distinct processes, such that the gate electrodes 102 may be different materials and/or have a different number of layers. Various masking steps may be used to mask and expose appropriate regions when using distinct processes.

After the filling of the second recesses 98, a planarization process, such as a CMP, may be performed to remove the excess portions of the gate dielectric layers 100 and the material of the gate electrodes 102, which excess portions are over the top surface of the first ILD 96. The remaining portions of material of the gate electrodes 102 and the gate dielectric layers 100 thus form replacement gate structures of the resulting nano-FETs. The gate electrodes 102 and the gate dielectric layers 100 may be collectively referred to as “gate structures.”

FIG. 17C illustrates a detailed view of various elements of FIG. 15B, including the epitaxial source/drain regions 92, the gate dielectric layers 100, the gate electrodes 102, the second nanostructures 54, and the inner spacers 90. In some embodiments, illustrated by FIG. 17C, a residue of the sacrificial material 72 may remain on the inner spacers 90, such as between the inner spacers 90 and the gate dielectric layers 100/gate electrodes 102, despite the above-described processes (including the treatment process illustrated in FIGS. 9A and 9B). For example, the sacrificial material 72 may not be fully removed, and the gate dielectric layers 100 may be formed on the remaining sacrificial material 72. Because the sacrificial material 72 is an insulating material (e.g., silicon oxide), and because the sacrificial material layer 71 was deposited only to a relatively thin thickness, the remaining residue may not significantly impact the electrical performance of the resulting device.

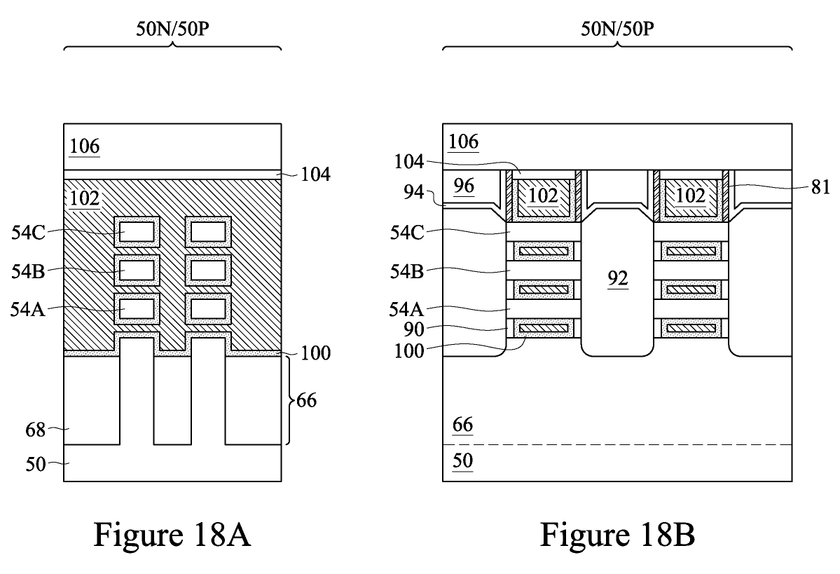

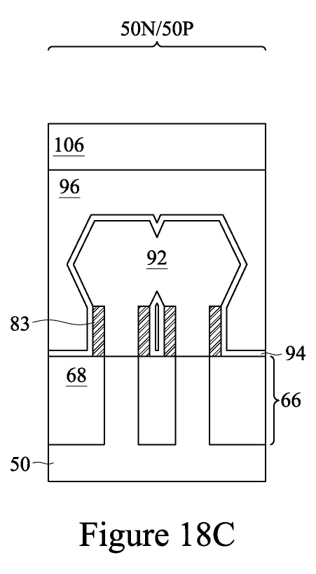

In FIGS. 18A-18C, the gate structure (including the gate dielectric layers 100 and the corresponding overlying gate electrodes 102) is recessed, so that a recess is formed directly over the gate structure and between opposing portions of gate spacers 81 (best illustrated in FIG. 18B). A gate mask 104 comprising one or more layers of dielectric material, such as silicon nitride, silicon oxynitride, or the like, is filled in the gate recess, followed by a planarization process to remove excess portions of the dielectric material extending over the first ILD 96. Subsequently formed gate contacts (such as the contacts 114, discussed below with respect to FIGS. 20A-20C) penetrate through the gate mask 104 to contact the top surface of the recessed gate electrodes 102.

As further illustrated by FIGS. 18A-18C, a second ILD 106 is deposited over the first ILD 96 and over the gate mask 104. In some embodiments, the second ILD 106 is a flowable film formed by FCVD. In some embodiments, the second ILD 106 is formed of a dielectric material such as PSG, BSG, BPSG, USG, or the like, and may be deposited by any suitable method, such as CVD, PECVD, or the like.

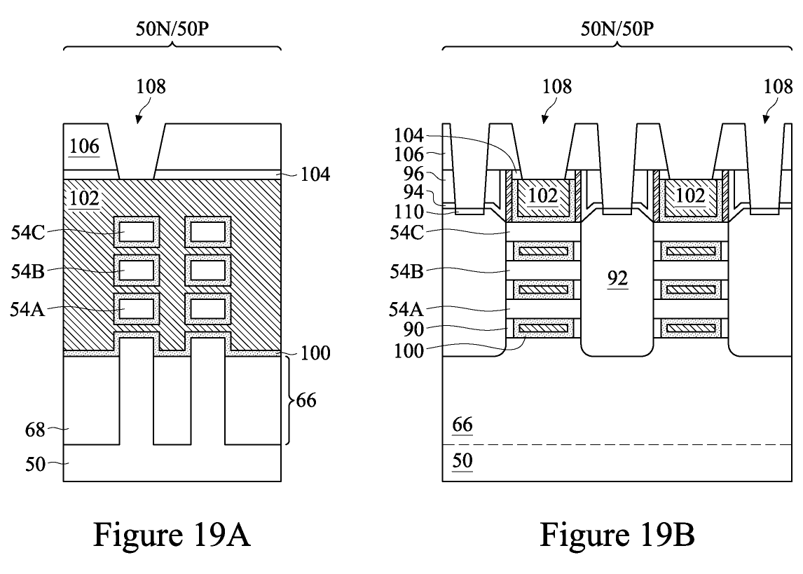

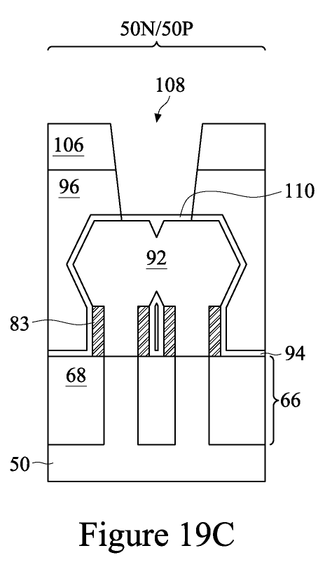

In FIGS. 19A-19C, the second ILD 106, the first ILD 96, the CESL 94, and the gate masks 104 are etched to form third recesses 108 exposing surfaces of the epitaxial source/drain regions 92 and/or the gate structure. The third recesses 108 may be formed by etching using an anisotropic etching process, such as RIE, NBE, or the like. In some embodiments, the third recesses 108 may be etched through the second ILD 106 and the first ILD 96 using a first etching process; may be etched through the gate masks 104 using a second etching process; and may then be etched through the CESL 94 using a third etching process. A mask, such as a photoresist, may be formed and patterned over the second ILD 106 to mask portions of the second ILD 106 from the first etching process and the second etching process.

In some embodiments, the etching process may over-etch, and therefore, the third recesses 108 extend into the epitaxial source/drain regions 92 and/or the gate structure, and a bottom of the third recesses 108 may be level with (e.g., at a same level, or having a same distance from the substrate), or lower than (e.g., closer to the substrate) the epitaxial source/drain regions 92 and/or the gate structure. Although FIGS. 26B illustrate the third recesses 108 as exposing the epitaxial source/drain regions 92 and the gate structure in a same cross section, in various embodiments, the epitaxial source/drain regions 92 and the gate structure may be exposed in different cross-sections, thereby reducing the risk of shorting subsequently formed contacts.

After the third recesses 108 are formed, silicide regions 110 are formed over the epitaxial source/drain regions 92. In some embodiments, the silicide regions 110 are formed by first depositing a metal (not shown) capable of reacting with the semiconductor materials of the underlying epitaxial source/drain regions 92 (e.g., silicon, silicon germanium, germanium) to form silicide or germanide regions, such as nickel, cobalt, titanium, tantalum, platinum, tungsten, other noble metals, other refractory metals, rare earth metals or their alloys, over the exposed portions of the epitaxial source/drain regions 92, then performing a thermal anneal process to form the silicide regions 110. The un-reacted portions of the deposited metal are then removed, e.g., by an etching process. Although silicide regions 110 are referred to as silicide regions, silicide regions 110 may also be germanide regions, or silicon germanide regions (e.g., regions comprising silicide and germanide). In an embodiment, the silicide regions 110 comprise TiSi, and have a thickness in a range between about 2 nm and about 10 nm.

Next, in FIGS. 20A-20C, contacts 112 and 114 (may also be referred to as contact plugs) are formed in the third recesses 108. The contacts 112 and 114 may each comprise one or more layers, such as barrier layers, diffusion layers, and fill materials. For example, in some embodiments, the contacts 112 and 114 each include a barrier layer and a conductive material, and is electrically coupled to the underlying conductive feature (e.g., gate electrode 102 and/or silicide region 110 in the illustrated embodiment). The contacts 114 are electrically coupled to the gate electrode 102 and may be referred to as gate contacts, and the contacts 112 are electrically coupled to the silicide regions 110 and may be referred to as source/drain contacts. The barrier layer may include titanium, titanium nitride, tantalum, tantalum nitride, or the like. The conductive material may be copper, a copper alloy, silver, gold, tungsten, cobalt, aluminum, nickel, or the like. A planarization process, such as a CMP, may be performed to remove excess material from a surface of the second ILD 106.

For brevity and ease of illustration, the above-discussed embodiments illustrate processes and resulting structures wherein devices formed in the n-type region 50N and devices formed in the p-type region 50P are formed using the same processes and materials. Those skilled in the art will recognize, however, that in many embodiments, different materials and/or different processes might be employed in the n-type region 50N and the p-type region 50P (in addition those different processes and materials that are specifically discussed above). As but one example, the nanostructures 55 in the n-type region 50N might have a different composition of layers, a different number of layers, a different shape, and/or a different width than nanostructures 55 in the p-type region 50P. Similarly, the composition of sacrificial material 72 in n-type region 50N could be the same as or could be different than the sacrificial material 72 in the p-type region 50P. Other variations and differences between the processes and resulting structures in n-type region 50N and p-type region 50P will become apparent to those skilled in the art, once informed by the present disclosure and through application of routine experimentation, and are within the contemplated scope of this disclosure.

In one aspect, some embodiments disclose herein may provide for a method of forming a device, the method comprising forming over a surface of a fin a stack of channel regions, individual channel regions being separated by respective gaps, applying a surface treatment to sidewalls of the channel regions and to the surface of the fin, the surface treatment causing the sidewalls of the channel regions and the surface of the fin to be less susceptible to deposition of a sacrificial material layer, relative to prior to the surface treatment, and depositing the sacrificial material layer on the channel regions and on the surface of the fin, wherein the surface treatment causes deposition of the sacrificial material to occur to a lesser extent on the sidewalls of the channel regions and the surface of the fin relative to on tops and bottoms of the channel regions. The method further includes etching back the sacrificial material layer from the sidewalls of the channel regions and the surface of the fin to form sacrificial material structures within the respective gaps.

In another aspect, some embodiments disclosed herein may provide for a method of forming a device, the method comprising forming a stack of alternating layers of first semiconductor material and second semiconductor material extending from a semiconductor fin, the stack having a first width in a first direction, removing layers of second semiconductor material from the stack to form a stack of layers of first semiconductor material, respective layers of first semiconductor material separated by respective first gaps, and a lowest layer of first semiconductor material separated from the semiconductor fin by a second gap, and applying a surface treatment to sidewalls of the layers of first semiconductor material and to sidewalls of the semiconductor fin to change a property of the sidewalls of the layers of first semiconductor material and at least a top surface of the semiconductor fin. The method further incudes depositing a sacrificial material layer on the layers of first semiconductor material and on the semiconductor fin to fill the first gaps and the second gap, wherein the sacrificial material layer is deposited within the first gaps and within the second gap to a second width, greater than the first width in the first direction, and to a first thickness, and further wherein the sacrificial material layer is deposited to a second thickness on the sidewalls of the layers of first semiconductor material and the semiconductor fin, the second thickness being less than the first thickness, etching back the sacrificial material layer to decrease the second thickness of the sacrificial material layer on the sidewalls of the layers of first semiconductor material and the semiconductor fin to a third thickness less than the second thickness and to recess the sacrificial material within the first gaps and the second gap to a third width, less than the first width in the first direction, thereby forming recesses in the sacrificial material layer in the first gaps and the second gap, and filling the recesses in the first gaps and the second gap with a spacer.

In yet another aspect, some embodiments disclosed herein may include a device comprising a semiconductor fin protruding from a substrate, a first stack of channel regions extending from the semiconductor fin and a second stack of channel regions extending from the semiconductor fin and laterally displaced from the first stack of channel regions, a first gate structure being interposed between respective channel regions of the first stack of channel regions, and a second gate structure being interposed between respective channel regions of the second stack of channel regions, and a source/drain region on the semiconductor fin and interposed between the first stack of channel regions and the second stack of channel regions, the source/drain region being in contact with the respective channel regions of the first stack of channel regions and with the respective channel regions of the second stack of channel regions, and an interface between the source/drain region and the semiconductor fin, wherein the semiconductor fin comprises a silicon-containing material, and further wherein a portion of the semiconductor fin adjacent the interface contains nitrogen at a mole percentage nitrogen / silicon ration of up to 0.1.

Embodiments disclosed herein may provide for a 1 device comprising a first transistor comprising a first active region and a first base region on a substrate, the first active region including a stack of first channel regions extending above the first base region, respective first channel regions of the stack of first channel regions being separated by respective first gaps, and a second transistor comprising a second active region and a second base region on the substrate, the second active region including a stack of second channel regions extending above the second base region, respective second channel regions of the stack of second channel regions being separated by respective second gaps. The device may further include an isolation feature disposed between the first base region and the second base region, wherein the isolation feature interfaces a sidewall of the first base region and a sidewall of the second base region, a first gate structure overlying a top first channel region of the stack of first channel regions and extending between respective first channel regions of the stack of first channel regions, and a second gate structure overlying a top second channel region of the stack of second channel regions and extending between respective second channel regions of the stack of second channel regions, wherein the first gate structure comprises a first gate dielectric layer and at least one first metal layer over the first gate dielectric layer and the second gate structure comprises a second gate dielectric layer and at least one second metal layer over the second gate dielectric layer, a source/drain region interjacent the stack of first channel regions and the stack of second channel regions, the source/drain region being in contact with the respective first channel regions and with the respective second channel, the source/drain region including a first semiconductor layer with a first element and a second semiconductor layer with the first element, wherein a concentration of the first element of the first semiconductor layer changes in a direction towards the substrate, and a height of the source/drain region is different from a width of the source/drain region in a cross-sectional view, and an interface between the source/drain region and the first base region, wherein the first base region contains nitrogen at a mole percentage nitrogen / silicon ration of 0.1 or less at the interface.

Other embodiments disclosed herein may provide for a method including steps of forming a stack of alternating first semiconductor layers and second semiconductor layers over a fin extending from a substrate, forming a dummy gate over a channel region of the stack, etching a recess through the stack on a side of the dummy gate, the recess extending into the fin and exposing sidewalls of the first semiconductor layers and of the second semiconductor layers, removing the first semiconductor layers through the recess to form gaps between adjacent ones of the second semiconductor layers and between a lowest one of the second semiconductor layers and the fin, the removing exposing a surface of the fin and sidewalls of the second semiconductor layers;, and applying a surface treatment to the exposed sidewalls of the second semiconductor layers and to the exposed surface of the fin, the surface treatment rendering the sidewalls of the second semiconductor layers and the surface of the fin less susceptible to deposition of a sacrificial material relative to prior to the surface treatment. The method may further include steps of after the surface treatment, depositing the sacrificial material through the recess, the sacrificial material filling the gaps to a first thickness and being deposited on the sidewalls of the second semiconductor layers and on the surface of the fin to a second thickness less than the first thickness, etching back the sacrificial material to form sacrificial structures within the gaps and to remove the sacrificial material from the sidewalls of the second semiconductor layers and from the surface of the fin, forming inner spacers on sidewalls of the sacrificial structures, epitaxially growing a source/drain region in the recess on the surface of the fin, the sacrificial structures from the gaps, and forming a gate structure in the gaps, the gate structure surrounding the second semiconductor layers.

Other embodiments disclosed herein may provide for a method including the steps of providing a workpiece comprising a semiconductor strip protruding from a base region and a plurality of semiconductor sheets, wherein the semiconductor sheets are vertically spaced-apart and are held above the semiconductor strip, the semiconductor sheets semiconductor sheets bounding a plurality of cavities, conditioning exposed faces of the semiconductor sheets and an upper face of the semiconductor strip to lower an affinity of the exposed faces and the upper face for a disposable interposer material, introducing the disposable interposer material into the cavities, the disposable interposer material accumulating within the cavities to a first extent and accumulating on the conditioned faces and the conditioned upper face to a second extent smaller than the first extent, recessing the disposable interposer material to clear the disposable interposer material from the conditioned faces and the conditioned upper face while retaining disposable interposer plugs occupying the cavities, and supplanting the disposable interposer plugs with conductive gate members encircling the semiconductor sheets.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device comprising:
a first transistor comprising a first active region and a first base region on a substrate, the first active region including a stack of first channel regions extending above the first base region, respective first channel regions of the stack of first channel regions being separated by respective first gaps;
a second transistor comprising a second active region and a second base region on the substrate, the second active region including a stack of second channel regions extending above the second base region, respective second channel regions of the stack of second channel regions being separated by respective second gaps;
an isolation feature disposed between the first base region and the second base region, wherein the isolation feature interfaces a sidewall of the first base region and a sidewall of the second base region;
a first gate structure overlying a top first channel region of the stack of first channel regions and extending between respective first channel regions of the stack of first channel regions, and a second gate structure overlying a top second channel region of the stack of second channel regions and extending between respective second channel regions of the stack of second channel regions, wherein the first gate structure comprises a first gate dielectric layer and at least one first metal layer over the first gate dielectric layer and the second gate structure comprises a second gate dielectric layer and at least one second metal layer over the second gate dielectric layer;
a source/drain region interjacent the stack of first channel regions and the stack of second channel regions, the source/drain region being in contact with the respective first channel regions and with the respective second channel, the source/drain region including a first semiconductor layer with a first element and a second semiconductor layer with the first element, wherein a concentration of the first element of the first semiconductor layer changes in a direction towards the substrate, and a height of the source/drain region is different from a width of the source/drain region in a cross-sectional view; and
an interface between the source/drain region and the first base region, wherein the first base region contains nitrogen at a mole percentage nitrogen / silicon ration of 0.1 or less at the interface.

2. The device of claim 1, wherein the first base region comprises a first fin structure protruding from the substrate and having a longitudinal axis extending in a first direction, the second base region comprises a second fin structure protruding from the substrate and having a longitudinal axis extending in the first direction, and the first gate structure has a longitudinal axis extending in a second direction orthogonal to the first direction, when viewed from a top-down perspective and further wherein the first gate structure overlies the first base region and the second base region when viewed from a cross-sectional perspective.

3. The device of claim 1, wherein the respective first channel regions comprise a first semiconductor material and the respective second channel regions comprises a second semiconductor material different from the first semiconductor material.

4. The device of claim 1, wherein sidewalls of the respective first channel regions and the respective second channel regions comprise a mole percentage nitrogen / silicon ration of 0.1 or less.

5. A method of forming a device, the method comprising:
forming a stack of alternating first semiconductor layers and second semiconductor layers over a fin extending from a substrate;
forming a dummy gate over a channel region of the stack;
etching a recess through the stack on a side of the dummy gate, the recess extending into the fin and exposing sidewalls of the first semiconductor layers and of the second semiconductor layers;
removing the first semiconductor layers through the recess to form gaps between adjacent ones of the second semiconductor layers and between a lowest one of the second semiconductor layers and the fin, the removing exposing a surface of the fin and sidewalls of the second semiconductor layers;
applying a surface treatment to the exposed sidewalls of the second semiconductor layers and to the exposed surface of the fin, the surface treatment rendering the sidewalls of the second semiconductor layers and the surface of the fin less susceptible to deposition of a sacrificial material relative to prior to the surface treatment;
after the surface treatment, depositing the sacrificial material through the recess, the sacrificial material filling the gaps to a first thickness and being deposited on the sidewalls of the second semiconductor layers and on the surface of the fin to a second thickness less than the first thickness;
etching back the sacrificial material to form sacrificial structures within the gaps and to remove the sacrificial material from the sidewalls of the second semiconductor layers and from the surface of the fin;
forming inner spacers on sidewalls of the sacrificial structures;
epitaxially growing a source/drain region in the recess on the surface of the fin;
removing the sacrificial structures from the gaps; and
forming a gate structure in the gaps, the gate structure surrounding the second semiconductor layers.

6. The method of claim 5, wherein applying the surface treatment comprises applying a nitrogen-containing plasma treatment.

7. The method of claim 6, wherein the nitrogen-containing plasma treatment comprises an NH₃ plasma.

8. The method of claim 5, wherein applying the surface treatment comprises applying a thermal treatment.

9. The method of claim 5, wherein applying the surface treatment renders the sidewalls of the second semiconductor layers and the surface of the fin more hydrophobic relative to prior to the surface treatment.

10. The method of claim 5, wherein the sidewalls of the second semiconductor layers and the surface of the fin include dangling silicon bonds prior to the surface treatment, and wherein applying the surface treatment hydrogen-passivates the dangling silicon bonds.

11. The method of claim 5, wherein applying the surface treatment treats the sidewalls of the second semiconductor layers without treating top surfaces and bottom surfaces of the second semiconductor layers, the top surfaces and the bottom surfaces being shielded by overlying structures during the surface treatment.

12. The method of claim 5, wherein the sacrificial material comprises silicon oxide.

13. The method of claim 5, wherein depositing the sacrificial material comprises a flowable chemical vapor deposition (FCVD) process.

14. The method of claim 5, further comprising, after depositing the sacrificial material, performing a bake process on the sidewalls of the second semiconductor layers and on the surface of the fin.

15. The method of claim 14, further comprising, after depositing the sacrificial material, performing a bake process, wherein after the bake process a portion of the fin at the surface of the fin contains nitrogen at a mole percentage ratio of nitrogen to silicon of up to 0.1 to 1.

16. A method comprising:
providing a workpiece comprising a semiconductor strip protruding from a base region and a plurality of semiconductor sheets, wherein the semiconductor sheets are vertically spaced-apart and are held above the semiconductor strip, the semiconductor sheets semiconductor sheets bounding a plurality of cavities;
conditioning exposed faces of the semiconductor sheets and an upper face of the semiconductor strip to lower an affinity of the exposed faces and the upper face for a disposable interposer material;
introducing the disposable interposer material into the cavities, the disposable interposer material accumulating within the cavities to a first extent and accumulating on the conditioned faces and the conditioned upper face to a second extent smaller than the first extent;
recessing the disposable interposer material to clear the disposable interposer material from the conditioned faces and the conditioned upper face while retaining disposable interposer plugs occupying the cavities; and
supplanting the disposable interposer plugs with conductive gate members encircling the semiconductor sheets.

17. The method of claim 16, wherein conditioning the exposed faces and the upper face comprises exposing the faces to a nitrogen-bearing plasma.

18. The method of claim 16, wherein conditioning the exposed faces and the upper face comprises a thermal exposure.

19. The method of claim 16, wherein the conditioning acts upon lateral faces of the semiconductor sheets while leaving upper and lower faces of the semiconductor sheets unconditioned, the upper and lower faces being obstructed by overlying features during the conditioning.

20. The method of claim 16, further comprising, after introducing the disposable interposer material, subjecting the workpiece to a bake, wherein following the bake a portion of the semiconductor strip at the upper face retains nitrogen at a mole percentage ratio of nitrogen to silicon of up to 0.1 to 1.
